(19) United States
(12) Patent Application Publication
(10) Pub. No.: US 2011/0221026 A1
(43) Pub. Date: Sep. 15, 2011

(54) PHOTOVOLTAIC DEVICE INCLUDING A SUBSTRATE OR A FLEXIBLE SUBSTRATE AND METHOD FOR MANUFACTURING THE SAME

(76) Inventor: Seung-Yeop Myong, Seoul (KR)

(21) Appl. No.: 13/048,300

(22) Filed: Mar. 15, 2011

(30) Foreign Application Priority Data
Mar. 15, 2010 (KR) 10-2010-0022626

(51) Int. Cl. H01L 31/102; H01L 31/18

(52) U.S. Cl. 257/461; 438/98; 257/E31.061; 257/E31.126

(57) ABSTRACT

Disclosed is a photovoltaic device. The photovoltaic device of the present invention includes: a first electrode and a second electrode, which are sequentially placed on a substrate; a first photoelectric conversion layer being placed between the first electrode and the second electrode, and including an n-type semiconductor layer, an intrinsic semiconductor layer and a p-type semiconductor layer, which are sequentially stacked; a second photoelectric conversion layer being placed between the first photoelectric conversion layer and the second electrode, and including an n-type semiconductor layer, an intrinsic semiconductor layer and a p-type semiconductor layer, which are sequentially stacked; and light transmitting particles placed within the second electrode.

### CROSS-REFERENCE TO RELATED APPLICATION

This application claims priority under 35 U.S.C. §119 to Korean Patent Application No. 10-2010-0022626 filed on Mar. 15, 2010, the entirety of which is hereby incorporated by reference.

### FIELD OF THE INVENTION

The present invention is related to a photovoltaic device including a substrate or flexible substrate and a method for manufacturing the same.

### BACKGROUND OF THE INVENTION

Recently, as existing energy resources like oil and coal and the like are expected to be exhausted, much attention is increasingly paid to alternative energy sources which can be used in place of the existing energy sources. As an alternative energy source, sunlight energy is abundant and has no environmental pollution. Therefore, more and more attention is paid to the sunlight energy.

A photovoltaic device, that is, a solar cell directly converts sunlight energy into electrical energy. The photovoltaic device mainly uses photovoltaic effect of semiconductor junction. In other words, when light is incident on and absorbed by a semiconductor p-i-n junction doped with p-type impurity and n-type impurity respectively, light energy generates electrons and holes within the semiconductor and the electrons and the holes are separated from each other by an internal field. As a result, a photo-electro motive force is generated between both ends of the p-i-n junction. Here, when electrodes are formed at both ends of the junction and connected with wires, electric current flows externally through the electrodes and the wires.

In order that the existing energy sources such as oil is substituted with the sunlight energy source, it is necessary to provide a photovoltaic device with high photovoltaic conversion efficiency.

### SUMMARY OF THE INVENTION

One aspect of the present invention is a photovoltaic device. The photovoltaic device includes: a first electrode and a second electrode, which are sequentially placed on a substrate; a first photoelectric conversion layer being placed between the first electrode and the second electrode, and including an n-type semiconductor layer, an intrinsic semiconductor layer and a p-type semiconductor layer, which are sequentially stacked; a second photoelectric conversion layer being placed between the first photoelectric conversion layer and the second electrode, and including an n-type semiconductor layer, an intrinsic semiconductor layer and a p-type semiconductor layer, which are sequentially stacked; and light transmitting particles placed within the second electrode.

Another aspect of the present invention is a photovoltaic device. The photovoltaic device includes: a first electrode and a second electrode, which are sequentially placed on a substrate; a first photoelectric conversion layer placed between the first electrode and the second electrode; a second photoelectric conversion layer placed between the first photoelectric conversion layer and the second electrode; and light transmitting particles placed within the second electrode closer to a light incident side than the first electrode.

The diameter of the light transmitting particle is equal to or larger than 50 nm and equal to or smaller than 800 nm.

The optical band gap of the intrinsic semiconductor layer of the first photoelectric conversion layer is smaller than the optical band gap of the intrinsic semiconductor layer of the second photoelectric conversion layer.

The substrate may be a flexible substrate.

The light transmitting particle is composed of a metal oxide.

Further another aspect of the present invention is a method for manufacturing a photovoltaic device. The method includes: providing a substrate on which a first electrode, a first photoelectric conversion layer and a second photoelectric conversion layer are sequentially formed, the first photoelectric conversion layer including an n-type semiconductor layer, an intrinsic semiconductor layer and a p-type semiconductor layer, which are sequentially stacked, the second photoelectric conversion layer including an n-type semiconductor layer, an intrinsic semiconductor layer and a p-type semiconductor layer, which are sequentially stacked; and forming a second electrode on the second photoelectric conversion layer, the second electrode surrounding light transmitting particles.

The forming the second electrode includes: forming a portion of the second electrode on the second photoelectric conversion layer; disposing the light transmitting particles on the portion of the second electrode; and forming the rest of the second electrode to cover the light transmitting particle.

The disposing the light transmitting particles includes: applying volatile solution having the light transmitting particles mixed therewith on the portion of the second electrode; and removing the volatile solution by a heating process.

The diameter of the light transmitting particle is equal to or larger than 50 nm and equal to or smaller than 800 nm.

The substrate may be a flexible substrate.

The volatile solution is removed at a temperature equal to or more than 25° C. and equal to or less than 180° C.

The volatile solution is applied by a spray method or an inkjet printing method.

The light transmitting particle is composed of a metal oxide.

### BRIEF DESCRIPTION OF THE DRAWINGS

FIGS. 1a to 1c show a method for manufacturing a photovoltaic device according to an embodiment of the present invention.

FIG. 2 shows an anti-reflection operation of the photovoltaic device according to the embodiment of the present invention.

FIG. 3 shows a photovoltaic device according to the embodiment of the present invention.

### DETAILED DESCRIPTION

An embodiment of the present invention will be described in detail with reference to the drawings.

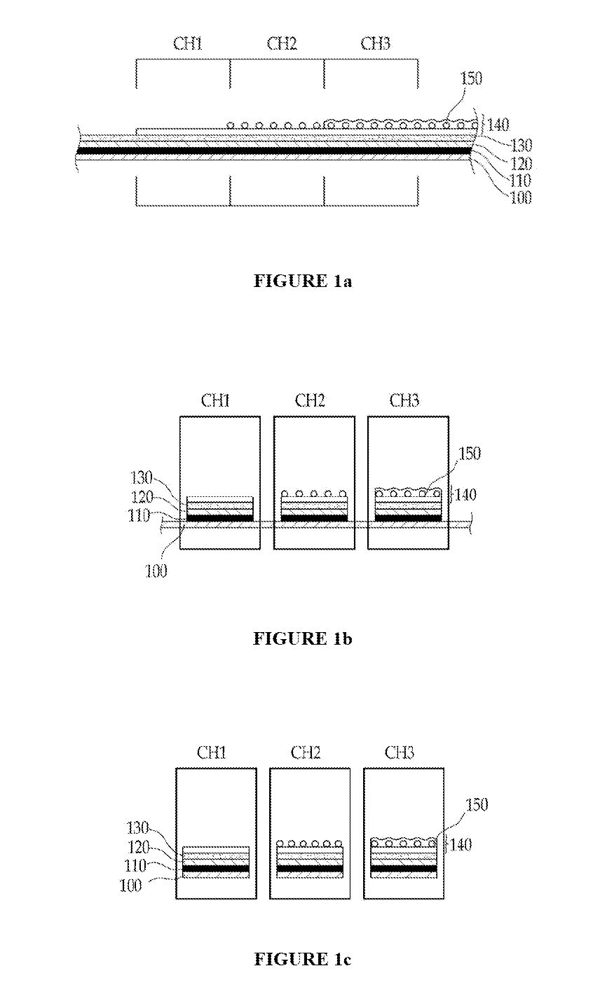

FIGS. 1a to 1c show a method for manufacturing a photovoltaic device according to an embodiment of the present invention. FIGS. 1a to 1c show photovoltaic devices, each of which is produced by a roll-to-roll manufacturing system, a stepping roll manufacturing system and an in-line manufacturing system respectively.

As shown in FIGS. 1a to 1c, a substrate 100 is provided, on which a first electrode 110, a first photoelectric conversion layer 120 and a second photoelectric conversion layer 130 are sequentially formed. Here, the first photoelectric conversion layer 120 and the second photoelectric conversion layer 130 include an n-type semiconductor layer, an intrinsic semiconductor layer and a p-type semiconductor layer, which are sequentially stacked. The n-type semiconductor layer is formed by using hydrogen gas, silane gas and impurity gas including group V elements. The intrinsic semiconductor layer is formed by using hydrogen gas and silane gas without impurity gas. The p-type semiconductor layer is formed by using hydrogen gas, silane gas and impurity gas including group III elements.

When the substrate 100 is provided as described above, a second electrode 140 surrounding light transmitting particles 150 is formed on the second photoelectric conversion layer 130. In order to form the second electrode 140, a portion of the second electrode 140 is formed on the second photoelectric conversion layer 130. Subsequently, the light transmitting particles 150 are disposed on the portion of the second electrode 140, and then the rest of the second electrode 140 is formed to cover the light transmitting particles 150.

In order that the second electrode 140 is formed in the manner above, the substrate 100 on which the first electrode 110, the first photoelectric conversion layer 120 and the second photoelectric conversion layer 130 are sequentially formed is transferred into a process chamber CH1. The process chamber CH1 is used to form a portion of the second electrode 140. In the process chamber CH1, the portion of the second electrode 140 is formed on the second photoelectric conversion layer 130 by using a sputtering method or a metal organic chemical vapor deposition (MOCVD). Here, the second electrode 140 may be composed of light transmitting transparent conductive oxide (TCO).

The substrate 100 on which the portion of the second electrode 140 is formed is transferred to a process chamber CH2. In the process chamber CH2, volatile solution having light transmitting particles 150 mixed therewith is applied on the second electrode 140. The volatile solution may be applied by a spray method or an inkjet printing method. Through the spray method or the inkjet printing method, the volatile solution having the light transmitting particles 150 mixed therewith can be uniformly applied.

The volatile solution can be removed by heating process. Here, the heating process may be performed in the process chamber CH2 or in a separate process chamber. Through the heating process, the volatile solution can be removed and the light transmitting particles 150 remain on the portion of the second electrode 140. The volatile solution can be removed by a heating process at a temperature equal to or more than 25° C. and equal to or less than 180° C. The volatile solution cannot be easily removed at a temperature lower than 25° C. At a temperature higher than 180° C., hydrogen flows out from the first photoelectric conversion layer 120 and the second photoelectric conversion layer 130 and it causes the efficiency deterioration of the photovoltaic device.

Next, the substrate 100 is transferred into a process chamber CH3. In the process chamber CH3, the rest of the second electrode 140 is formed to cover the light transmitting particles 150.

Though not shown in the drawings, after the second electrode 140 is formed, a transparent encapsulant may be laminated on the second electrode 140 so as to protect the photovoltaic device from external environment in a long time period.

As described, above, the photovoltaic device according to the embodiment of the present invention is an n-i-p type photovoltaic device. In an n-i-p type photovoltaic device, the n-type semiconductor layer, the intrinsic semiconductor layer and the p-type semiconductor layer are sequentially stacked on the substrate 100. Accordingly, light is incident on the second electrode 140 prior to the first electrode 110. Moreover, since light reaches the second photoelectric conversion layer 130 prior to the first photoelectric conversion layer 120, the optical band gap of the intrinsic semiconductor layer of the first photoelectric conversion layer 120 is smaller than the optical band gap of the intrinsic semiconductor layer of the second photoelectric conversion layer 130.

In the n-i-p type photovoltaic device, light is incident through the second electrode 140. Therefore, when a texturing structure is formed at the interface between the second photoelectric conversion layer 130 and the second electrode 140, photoelectric conversion efficiency is increased due to light scattering. However, in the n-i-p type photovoltaic device; a texturing structure allowing sufficient light scattering is difficult to be formed at the interface between the second photoelectric conversion layer 130 and the second electrode 140.

For example, when ZnO is used as the second electrode 140, the texturing structure is formed as the ZnO grows on the second photoelectric conversion layer 130. Therefore, the texturing structure of the ZnO is formed on a ZnO surface opposite to the interface between the second photoelectric conversion layer 130 and the ZnO.

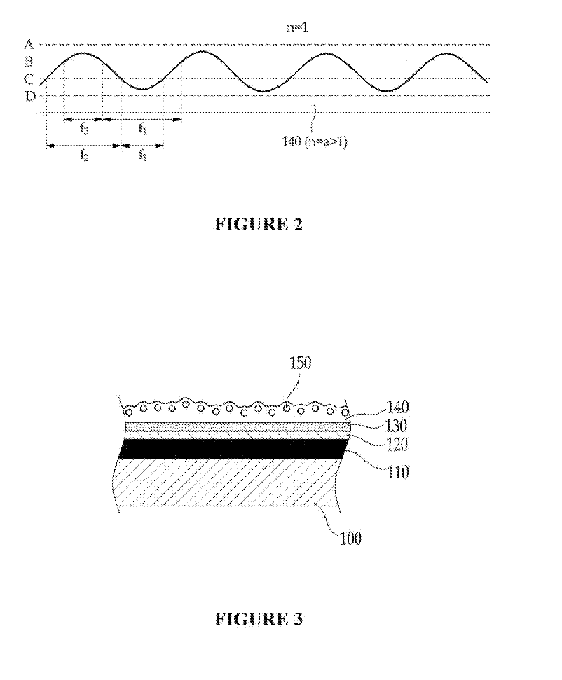

In the photovoltaic device according to the embodiment of the present invention, the light transmitting particles 150 are able to prevent the light reflection. As shown in FIG. 2, the surface of the second electrode 140 is textured by the light transmitting particles 150. Here, the refractive index (n=a) of the second electrode 140 is greater than the refractive index (n=1) of the air. In the embodiment of the present invention, when the second electrode 140 is composed of a light-transmitting conductive oxide, the refractive index (n=a) of the second electrode 140 is about 1.5.

Since only air exists in an extension line A, the refractive index in the extension line A is 1. The air and the second electrode 140 exist in an extension line B and an extension line C.

“f1” represents a volume fraction occupied by the air. “f2” represents a volume fraction occupied by the second electrode 140. A sum of “f1” and “f2” is 1.

In the extension line B, the volume fraction (f1) occupied by the air is greater than the volume fraction (f2) occupied by the second electrode 140. In the extension line C, the volume fraction (f2) occupied by the second electrode 140 increases and the volume fraction (f1) occupied by the air decreases. Therefore, when light is incident in the direction from the extension line B to the extension line C, the refractive index gradually increases.

Lastly, only the second electrode 140 exists in an extension line D. Therefore, the refractive index in the extension line D corresponds to the refractive index of the second electrode 140 greater than that of the air.

Therefore, when light is incident in the direction from the air to the second electrode 140, the refractive index gradually increases. Accordingly, light is prevented from being reflected at the surface of the second electrode 140. When light is incident on the second electrode 140, the texturing structure formed by the light transmitting particles 150 cause the refractive index to be changed not discontinuously but gradually, so that the amount of the reflected light is more reduced.

In the photovoltaic device according to the embodiment of the present invention, the light transmitting particles 150 scatter light. The light transmitting particles 150 are located within the second electrode 140 and close to the interface between the second photoelectric conversion layer 130 and the second electrode 140, so that the scattered light is easy to reach the second photoelectric conversion layer 130.

The light transmitting particle 150 is able to scatter light with the particular wavelength in accordance with its size. For example, when the diameter of the light transmitting particle 150 is equal to or larger than 50 nm and equal to or smaller than 800 nm, the light transmitting particle 150 is able to increase the scatter of visible light and infrared light. Moreover, the surface of the second electrode 140 is textured by the light transmitting particles 150, thereby the incident light can be scattered.

The light transmitting particle 150 may be composed of a metal oxide such as TiO₂, ZnO, SnO₂, InO₂, Al₂O₃ or an insulating oxide such as SiO₂. Since the light transmitting particle 150 is located within the second electrode 140, the light transmitting particle 150 composed of the metal oxide is able to prevent the resistance of the second electrode 140 from being increased.

In the embodiment of the present invention, the substrate 100 may be a flexible substrate, for example, metal foil or a polymer substrate. As shown in FIGS. 1a to 1b, in the roll-to-roll manufacturing system and the stepping roll manufacturing system, a low cost flexible substrate rolled in a roll is unwound and is transferred into the process chambers CH1, CH2 and CH3, so that productivity is improved.

In the roll-to-roll manufacturing system, while a roll (got shown) continuously rotates, the substrate 100 unwound from the roll passes through the process chambers. In the stepping roll manufacturing system, the roll rotates and stops repetitively. Here, while the roll rotates; a gate (not shown) or a top plate of each of the process chambers is opened and the substrate 100 moves. While the roll stops, the gate or top plate is closed and the corresponding layers are formed in each process chamber.

As shown in FIG. 1c, in the in-line manufacturing system, the substrate 100 like glass instead of the flexible substrate is transferred to the process chambers by a transfer means (not shown).

Next, the photovoltaic device according to the embodiment of the present invention will be described with reference to the drawings.

FIG. 3 shows the photovoltaic device according to the embodiment of the present invention. As shown in FIG. 3, the photovoltaic device according to the embodiment of the present invention includes a substrate 100, a first electrode 110, a second electrode 140, a first photoelectric conversion layer 120, a second photoelectric conversion layer 130 and light transmitting particles 150.

The first electrode 110 and the second electrode 140 are placed sequentially on the substrate 100. In the embodiment of the present invention, the substrate 100 may be a flexible substrate.

The first photoelectric conversion layer 120 is placed between the first electrode 110 and the second electrode 140, and includes an n-type semiconductor layer, an intrinsic semiconductor layer and a p-type semiconductor layer, which are sequentially stacked. That is, the first photoelectric conversion layer 120 corresponds to an n-i-p type photoelectric conversion layer.

The second photoelectric conversion layer 130 is placed between the first photoelectric conversion layer 120 and the second electrode 140. Like the first photoelectric conversion layer 120, the second photoelectric conversion layer 130 includes an n-type semiconductor layer, an intrinsic semiconductor layer and a p-type semiconductor layer, which are sequentially stacked.

The light transmitting particles 150 are placed within the second electrode 140. Such light transmitting particles 150 scatter light incident on the second electrode 140 prior to the first electrode 110.

Since the size, function and material of the light transmitting particle 150 have been described above, detailed description thereof will be omitted.

A transparent encapsulant for protecting the photovoltaic device may be formed on the second electrode 140 by a lamination process.

While the embodiment of the present invention has been described with reference to the accompanying drawings, it can be understood by those skilled in the art that the present invention can be embodied in other specific forms without departing from its spirit or essential characteristics. Therefore, the foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A photovoltaic device comprising:
a first electrode and a second electrode, which are sequentially placed on a substrate;
a first photoelectric conversion layer being placed between the first electrode and the second electrode, and including an n-type semiconductor layer, an intrinsic semiconductor layer and a p-type semiconductor layer, which are sequentially stacked;
a second photoelectric conversion layer being placed between the first photoelectric conversion layer and the second electrode, and including an n-type semiconductor layer, an intrinsic semiconductor layer and a p-type semiconductor layer, which are sequentially stacked; and
light transmitting particles placed within the second electrode.

2. The photovoltaic device of claim 1, wherein the diameter of the light transmitting particle is equal to or larger than 50 nm and equal to or smaller than 800 nm.

3. The photovoltaic device of claim 1, wherein the optical band gap of the intrinsic semiconductor layer of the first photoelectric conversion layer is smaller than the optical band gap of the intrinsic semiconductor layer of the second photoelectric conversion layer.

4. The photovoltaic device of claim 1, wherein the substrate is a flexible substrate.

5. The photovoltaic device of claim 1, wherein the light transmitting particle is composed of a metal oxide.

6. A photovoltaic device comprising:
a first electrode and a second electrode, which are sequentially placed on a substrate;
a first photoelectric conversion layer placed between the first electrode and the second electrode;
a second photoelectric conversion layer placed between the first photoelectric conversion layer and the second electrode; and
light transmitting particles placed within the second electrode closer to a light incident side than the first electrode.

7. The photovoltaic device of claim 6, wherein the diameter of the light transmitting particle is equal to or larger than 50 nm and equal to or smaller than 800 nm.

8. The photovoltaic device of claim 6, wherein the optical band gap of the intrinsic semiconductor layer of the first photoelectric conversion layer is smaller than the optical band gap of the intrinsic semiconductor layer of the second photoelectric conversion layer.

9. The photovoltaic device of claim 6, wherein the substrate is a flexible substrate.

10. The photovoltaic device of claim 6, wherein the light transmitting particle is composed of a metal oxide.

11. A method for manufacturing a photovoltaic device, the method comprising:
providing a substrate on which a first electrode, a first photoelectric conversion layer and a second photoelectric conversion layer are sequentially formed, the first photoelectric conversion layer including an n-type semiconductor layer, an intrinsic semiconductor layer and a p-type semiconductor layer, which are sequentially stacked, the second photoelectric conversion layer including an n-type semiconductor layer, an intrinsic semiconductor layer and a p-type semiconductor layer, which are sequentially stacked; and
forming a second electrode on the second photoelectric conversion layer, the second electrode surrounding light transmitting particles.

12. The method of claim 11, wherein the forming the second electrode comprises:
forming a portion of the second electrode on the second photoelectric conversion layer;
disposing the light transmitting particles on the portion of the second electrode; and
forming the rest of the second electrode to cover the light transmitting particles.

13. The method of claim 12, wherein the disposing the light transmitting particles comprises:
applying volatile solution having the light transmitting particles mixed therewith on the portion of the second electrode; and
removing the volatile solution by a heating process.

14. The method of claim 11, wherein the diameter of the light transmitting particle is equal to or larger than 50 nm and equal to or smaller than 800 nm.

15. The method of claim 11, wherein the substrate is a flexible substrate.

16. The method of claim 13, wherein the volatile solution is removed at a temperature equal to or more than 25° C. and equal to or less than 180° C.

17. The method of claim 13, wherein the volatile solution is applied by a spray method or an inkjet printing method.

18. The method of claim 11, wherein the light transmitting particle is composed of a metal oxide.
